(19) United States
(12) Patent Application Publication
(10) Pub. No.: US 2013/0335677 A1
(43) Pub. Date: Dec. 19, 2013

(54) Quantum Dot-Enhanced Display Having Dichroic Filter

(71) Applicant: APPLE INC., Cupertino, CA (US)

(72) Inventor: Chenhua You, San Jose, CA (US)

(73) Assignee: Apple Inc., Cupertino, CA (US)

(21) Appl. No.: 13/630,785

(22) Filed: Sep. 28, 2012

Related U.S. Application Data
(60) Provisional application No. 61/660,501, filed on Jun. 15, 2012.

(51) Int. Cl. H01L 33/04; G02F 1/13357; H01L 33/08

(52) U.S. Cl. 349/65; 257/13; 349/69; 257/E33.008

(57) ABSTRACT

A display device is provided. The display device includes a light source emitting a blue light and a light emitting layer including a first group of red quantum dots and a second group of green quantum dots. The light emitting layer is configured to absorb a first portion of the blue light from the light source to emit red light and green light and to transmit a second portion of the blue light. The display device also includes a dichroic filter layer configured to reflect a portion of the transmitted second portion of the blue light such that the reflected portion of the blue light is recycled in the light emitting layer and to transmit a remaining portion of the transmitted second portion of the blue light to output a white light.

### CROSS-REFERENCE TO RELATED APPLICATION

The present application claims priority to U.S. Provisional Application No. 61/660,501, entitled “Quantum Dot-Enhanced Display Having Dichroic Filter”, filed Jun. 15, 2012, the disclosure of which is incorporated herein by reference in its entirety.

### TECHNICAL FIELD

The present invention generally relates to display devices. More specifically, the invention relates to a display having a dichroic filter.

### BACKGROUND

A quantum dot-enhanced liquid crystal display uses quantum dots to facilitate display of electronic information. As one example, Quantum dots (QDs) are semiconductors in the form of nanocrystals that provide an alternative display. The electronic characteristics of the QDs are generally governed by the size and shape of the nanocrystals. Quantum dots of the same material, but with different sizes, can emit light of different colors when excited. More specifically, the emission wavelength of the QDs varies with a size and shape of the quantum dots. As one example, larger dots may emit longer wavelength light, such as red light while smaller QDs may emit shorter wavelength light, such as blue light or violet light. For example, quantum dots formed from cadmium selenide (CdSe) may be gradually tuned to emit light from the red region of the visible spectrum for a 5 nm diameter quantum dot, to the violet region for a 1.5 nm quantum dot. By varying dot size, the entire visible wavelength, ranging from about 460 nm (blue) to about 650 nm (red), may be reproduced.

One of the common issues with quantum dots is that they are potentially toxic. Cadmium-free quantum dots or heavy metal-free quantum dots may be desirable for consumer goods applications. In other words, it may be useful to reduce the cadmium (Cd) content in a product below a threshold such that the cadmium is present only in trace or minimal amounts. Quantum dots with a stable polymer coating may be nontoxic. Another issue is the high production cost for the quantum dots in the display.

There remains a need for designing the quantum dot-enhanced liquid crystal display to achieve reduced toxicity, improved performance, and lower cost in fabrication.

### SUMMARY

Embodiments described herein may provide a dichroic filter (DCF) on quantum dot-enhanced film (QDEF) in a liquid crystal display for transmitting a red light and a green light and a small portion of a blue light but reflecting most of the blue light, such that a white light is produced. The DCF helps reduce the density of quantum dots and thus may reduce toxic content, such as Cd content. The DCF also improves color and luminance uniformity. The DCF may also reduce quenching and thus manufacturing cost.

In one embodiment, a display device is provided. The display device includes a light source emitting a blue light, and a light emitting layer including a first group of red quantum dots and a second group of green quantum dots. The light emitting layer is configured to absorb a first portion of the blue light from the light source to emit red light and green light and to transmit a second portion of the blue light. The display device also includes a dichroic filter layer configured to reflect a portion of the transmitted second portion of the blue light such that the reflected portion of the blue light is recycled in the light emitting layer and to transmit a remaining portion of the transmitted second portion of the blue light to output a white light.

In another embodiment, a display device includes a light source emitting a blue light and a light emitting layer comprising a first group of red quantum dots and a second group of green quantum dots. The light emitting layer configured to absorb a first portion of the blue light from the light source to emit red light and green light and to transmit a second portion of the blue light. The display device also includes a dichroic filter layer configured to reflect a portion of the transmitted second portion of the blue light such that the reflected portion of the blue light is recycled in the light emitting layer and to transmit a remaining portion of the transmitted second portion of the blue light to output a white light. The display device further includes a liquid crystal display including a front polarizer, a rear polarizer, and a liquid crystal layer between the first polarizer and the second polarizer. The liquid crystal display also includes a plurality of color filters between the front polarizer and the liquid crystal layer. The liquid crystal display is configured to control pass of the white light from the dichroic filter through the color filters arranged in subpixels.

Additional embodiments and features are set forth in part in the description that follows, and in part will become apparent to those skilled in the art upon examination of the specification or may be learned by the practice of the invention. A further understanding of the nature and advantages of the present invention may be realized by reference to the remaining portions of the specification and the drawings, which forms a part of this disclosure.

### BRIEF DESCRIPTION OF THE DRAWINGS

FIG. 1A illustrates a conventional liquid crystal display (LCD) with an edge lit configuration (Prior art).

FIG. 1B illustrates a conventional liquid crystal display (LCD) with a direct lit configuration (Prior art).

FIG. 2 illustrates a quantum dot-enhanced display with a dichroic filter in an embodiment.

FIG. 3 illustrates a detailed structure of the dichroic filter (DCF) of FIG. 2 in an embodiment.

FIG. 4 illustrates transmittance versus wavelength for the dichroic filter of FIG. 3 and an emission curve of QDs in an embodiment.

FIG. 5 illustrates the recycling of blue light in the QDEF by the dichroic filter in an embodiment.

FIG. 6 illustrates color gamuts for the quantum dot-enhanced display of FIG. 2 and the LCD of FIG. 1 in an embodiment.

### DETAILED DESCRIPTION

The present disclosure may be understood by reference to the following detailed description, taken in conjunction with the drawings as briefly described below. It is noted that, for purposes of illustrative clarity, certain elements in the drawings may not be drawn to scale.

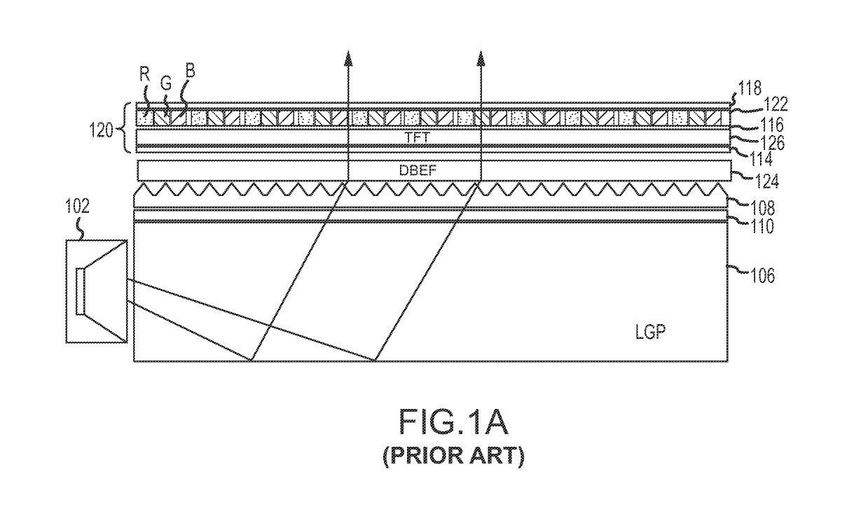

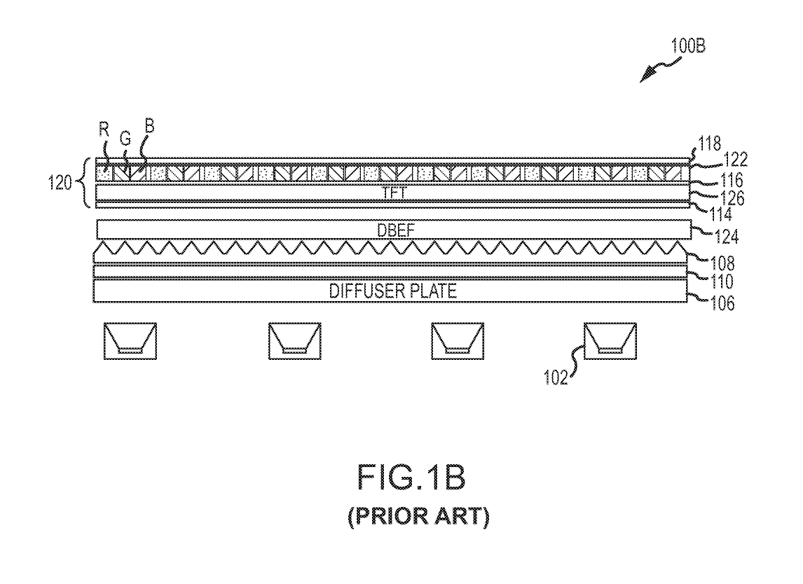

FIG. 1A illustrates a conventional liquid crystal display (LCD) with an edge lit backlight configuration. LCD 100A includes a primary light source or backlight source 102, a light guide panel (LGP) 106, and a LCD panel 120. The LCD 100 uses the LCD panel 120 with control electronics and the backlight source 102 to produce color images. The backlight source 102 provides white light.

The liquid crystal display panel 120 includes color filters 122 arranged in subpixels, such as a red color filter, a green color filter, and a blue color filter. The red, green, and blue filters 122 transmit a light having a specific wavelength of white light incident from the backlight source 102. The filters 122 transmit wavelengths of light corresponding to the color of each filter, and absorb other wavelengths. Accordingly, a light loss is generated in the liquid crystal display by the color filters. In order to display images having a sufficient brightness, the backlight source 102 is typically used. However, this generally causes an increase in power consumption by the liquid crystal display.

The LCD panel 120 also includes a front polarizer 118, a rear polarizer 114, a thin film transistor (TFT) 126, and liquid crystal 116 as well as electrodes (not shown). The color filters 122 are positioned between the liquid crystal 116 and the front polarizer 118. The TFT 126 is positioned between the liquid crystal 116 and the rear polarizer 114. Each pixel has a corresponding transistor or switch for controlling voltage applied to the liquid crystal 116. The liquid crystal 116 may include rod-shaped polymers that naturally form into thin layers with a natural alignment. The electrodes may be made of a transparent conductor, such as an indium-tin-oxide material (commonly referred to as “ITO”). The front and rear polarizers 118 and 114 may be set at right angles. Normally, the LCD panel 120 may be opaque. When a voltage is applied across the liquid crystal 116, the rod-shaped polymers align with the electric field and untwist such that the voltage controls the light output from the front polarizer 118. For example, when a voltage is applied to the liquid crystal 116, the liquid crystal 116 rotates so that there is a light output from the front polarizer 118.

For a conventional LCD, a white LED, a cold-cathode fluorescent lamps (CCFL) or an incandescent backlighting may be used. Generally, brighter light source may have a shorter life time and generate more heat.

As an example, the backlight source 102 includes one or more blue LEDs and yellow phosphor pumped by the blue LEDs to emit white light for LCD 100. The white light from the backlight source 102 travels toward the light guide panel (LGP) 106, through diffuser film 110 and prism 108 as well as double brightness enhanced film (DBEF) 124, which provides a uniform light backlight for the liquid crystal display panel 120. The phosphors may include transition metal compounds or rare earth compounds. Alternatively, the backlight source 102 may include a white LED that provides white light to the light guide panel 106. The white LED may use a blue LED with broad spectrum yellow phosphor, or a blue LED with red and green phosphors.

FIG. 1B illustrates a direct lit backlight configuration for the conventional LCD. As shown, the main differences from the edge lit configuration 100B include different arrangement of a number of LEDs and absence of the LGP 106. More specifically, the LEDs 102 are arranged to directly provide light to a diffuser plate 126, which is normally thicker than the diffuser film 110 and thus supports the diffuser film 110.

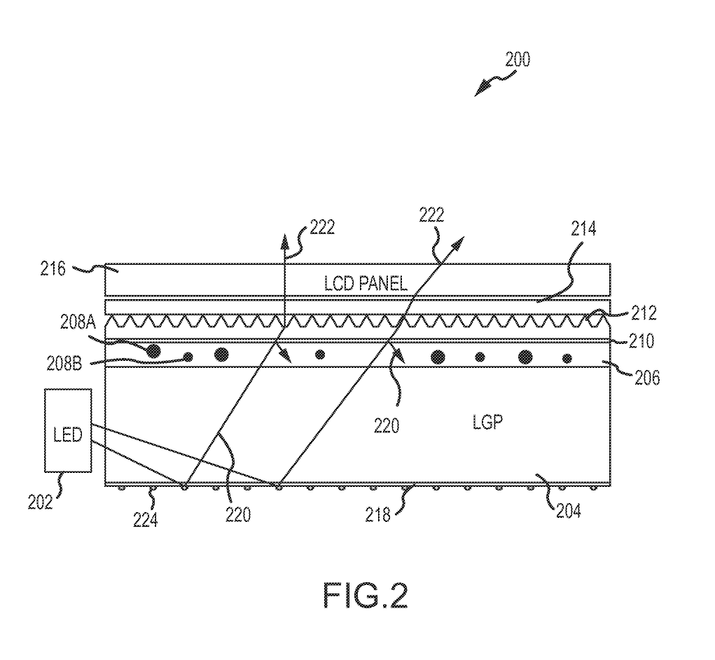

FIG. 2 illustrates a quantum dot-enhanced liquid crystal display with a dichroic filter (DCF) incorporated in a sample embodiment. Quantum dot-enhanced liquid crystal display 200 includes a light source 202, a light guide panel (LGP) 204, a quantum dot-enhanced film (QDEF) 206, a DCF 210, a LCD panel 216. The QD enhanced display 200 may also optionally include a prism 212 and a double brightness enhanced film (DBEF) 214. The light source 202 may be a blue light-emitting diode (LED) or a blue Gallium Nitride (GaN) LED.

To produce even lighting, a blue light from the light source 202 first passes through the LGP 204 that may include a series of unevenly-spaced bumps or light extraction features 224 and a reflector 218 behind the light extraction features 224. The LGP 204 diffuses the blue light through the series of unevenly-spaced bumps or light extraction features 224, as shown by blue light 220. The density of the bumps or light extraction features increases further away from the light source 202. The front face of the LGP 204 faces the LCD panel 216 and the back of the LGP 204 has the reflector 218, which guides otherwise wasted light back toward the LCD panel 216. In one example, the reflector 218 may be made of highly reflective material, such as white polyethylene terephthalate (PET) and in one embodiment reflects about 97% of all light impacting its surface.

The LCD panel 216 also includes color filters arranged in subpixels, a front polarizer, a rear polarizer, and liquid crystal as well as electrodes, similar to the LCD panel 120 for the conventional LCD 100. Generally, there is an air space between the LCD panel 216 and the DBEF 214.

Unlike the conventional LCD 100, instead of using the red phosphor 110A and green phosphor 110B, the QDEF 206 including red QDs 208A and green QDs 208B produces red color and green color, which are excited by the blue light from the light source 202. The QDEF 206 converts the color while diffusing the blue light 220 from the light source 202.

Generally, the QDEF 206 is configured to transmit a portion of the blue light 220 from the light source 202 such that white light 222 comes out of the QDEF 206. The QDEF 206 includes a group of red quantum dots (QDs) 208A and green QDs 208B, which actively convert the blue light 220 from the LED into red light and green light through the quantum dots. When the QDs 208A and 208B are irradiated by the blue light from the light source 202, the blue light causes the QDs 208A and 208B to photoluminescence and thereby produce secondary light. The color of the secondary light is generally a function of the size, size distribution and composition of the QDs 208A and 208B.

It will be appreciated by those skilled in the art that the QD enhanced display may vary in configuration. For example, other lit configuration may be used, including a direct lit configuration in some embodiment, similar to the direct lit configuration shown in FIG. 1B. The prism 212 may also be removed or substituted by other brightness enhancement component in an alternative embodiment. The DBEF 214 may be removed in another embodiment.

The QDEF 206 may include a host matrix. The QDEF 206 may also include red QDs and green QDs 208A and 208B disposed in the host matrix. The host matrix allows light from the light source 202 to pass through. The host matrix may be any polymer, such as polyacrylate, polystyrene, polyimide, polyacrylamide, polyethylene, polyvinyl, poly-diacetylene, polyphenylene-vinylene, polypeptide, polysaccharide, polysulfone, polypyrrole, polyimidazole, polythiophene, polyether, epoxies, silica glass, silica gel, siloxane, polyphosphate, hydrogel, agarose, cellulose, and the like.

Widely used methods of forming the QD include a chemical wet method or a chemical vapor. The chemical wet method mixes precursors with an organic solvent and grows particles to form the QD through a chemical reaction.

Enhancement or quenching of the radiation of the QDs may be achieved by adjusting the size of the QD, changing structure or adding other materials. Quenching may help increase light efficiency. Higher efficiency means that more red light or green light will be produced from red QDs and green QDs by using the same light source 202. When QDs are stuck to each other, for example, a red QD is stuck to a green QD, the red QD may be re-excited by the green QD, which may increase the light efficiency of the red light, but may reduce the light efficiency of the green light. Thus, it is desirable to have the QDs separated from each other in the host matrix. When the QD density is reduced because of the recycling of the blue light through use of the DCF, there will be less likely for the QDs to stick to each other and thus to improve light efficiency. Therefore, quenching may be minimized to reduce manufacturing cost.

As an example of the QD, a group II-VI compound, such as CdSe, CdTe, CdS, ZnSe, ZnTe, ZnS, HgTe, or HgS, may be used. Also, the QD may also have a core-shell structure. The core comprises at least one selected from the groups consisting of CdSe, CdTe, CdS, ZnSe, ZnTe, ZnS, HgTe, and HgS, and the shell comprises at least one selected from the groups consisting of CdSe, CdTe, CdS, ZnSe, ZnTe, ZnS, HgTe, and HgS. Further, a group III-V compound such as GaN, InAs, GaAs, GaInP may be applied to the core or shell.

As shown in FIG. 2 the DCF 210 is used in front of the QDEF 206 to recycle the blue light 220. The DCF 210 recycles the blue light 220 from the light source 202 within the QDEF 206 by reflecting a portion of the blue light 220, although the DCF 210 still transmits a small portion of the blue light 220 to provide the white light 222 to the LCD panel 216. This recycling of the blue light 220 helps reduce the CdSe content, and also improves color and luminance uniformity. Quenching will also be reduced as a result of reduced QD density.

The QD enhanced display 200 may optionally include brightness enhancement component, such as a prism 212 and a double brightness enhanced film (DBEF) 214. The brightness enhancement components are optically transparent. The prism 212 helps reduce beam angle and thus increases light intensity through the DBEF 214. The DBEF may be provided by manufacturers, such as 3M among others. The DBEF 214 is a reflective polarizer film which increases efficiency by repeatedly reflecting any unpolarized light back, which would otherwise be absorbed by the LCD's rear polarizer. The DBEF 214 is placed behind the liquid crystal display panel 216 without any other film in-between. The DBEF 214 may be mounted with its transmission axis substantially parallel to the transmission axis of the rear polarizer. The DBEF 214 helps recycle the white light 222 that would normally be absorbed by the rear polarizer (not shown) of the liquid crystal panel 216, and thus increases the brightness of the liquid crystal display panel 216.

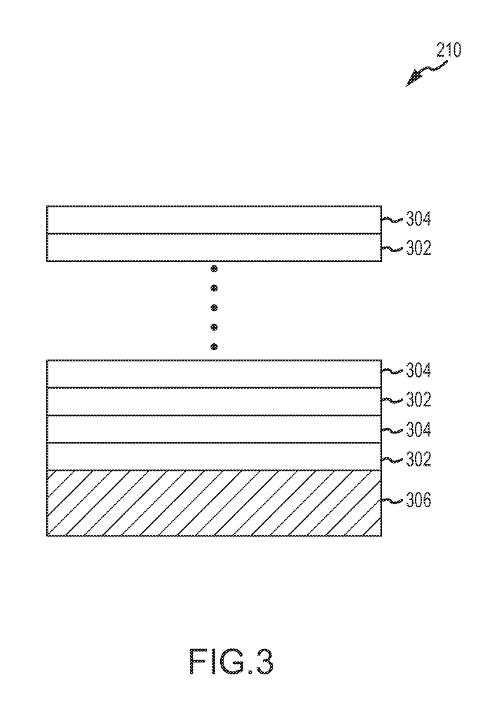

FIG. 3 illustrates a detailed structure of the DCF 210 in an embodiment. The DCF 210 is optically transparent. The DCF 210 may include alternating layers 302 and 304 of optical coatings with different refractive indexes and a glass substrate 306. For example, layer 302 has a first refractive index and layer 304 has a second refractive index different from the first refractive index. The interfaces between the alternating layers 302 and 304 of different refractive indexes produce phased reflections, selectively reinforcing certain wavelengths of light and interfering with other wavelengths. In this disclosure, each of layers 302 and 304 has a thickness of about ¼ of the wavelength of the blue light.

The DCF 210 may be fabricated by vacuum deposition. The DCF 210 may be coated on the QDEF 206. The DCF 210 may also be a separate sheet which is placed over the QDEF 206. The transmission and reflection band of the DCF 210 may need to be properly aligned with the spectra of red, green and blue light.

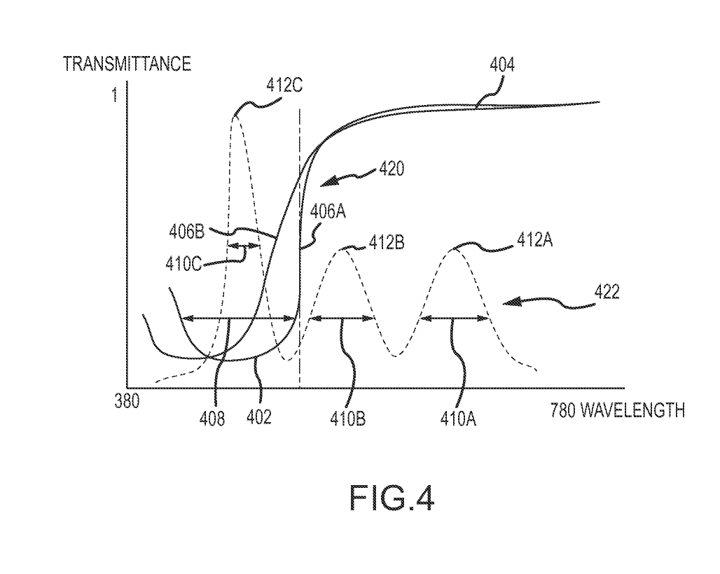

FIG. 4 illustrates an emission curve 422 of QDs and a transmittance curve 420 for the DCF 210. As shown in the emission curve 422, each of the red, green, and blue color bands 412A-C emitted from the QDs is separated from each other. In other words, an emission color bandwidth 410 of the QDs is relatively narrow. Each of the emission color bandwidth 410A-C for respective quantum dot 412A, 412B, 412C varies with color and material. For example, CdSe quantum dot may have a blue emission bandwidth 410 of about 35 nm. InP quantum dot may have a blue emission bandwidth 410 of about 45 nm, which is wider than that of the CdSe quantum dot.

As shown in FIG. 4, the DCF 210 also has a low transmittance over a blue region 402 (see transmittance curve 420). Typically, the transmittance of the DCF 210 is not zero. A small portion of the blue light 220 as shown in FIG. 2 is transmitted through the DCF 210, such that the white light 222 also shown in FIG. 2 will be produced by combining the blue light from the light source 202 with the red and green lights from the QDs 208A and 208B. The transmittance in the blue region 402 may be at certain percentage, for example 25%, but may not be more than 50%. The transmittance of the blue region 402 may vary with the number of the layers 302 and 304 in the DCF 210 (see FIG. 3). As shown in FIG. 4, the transmittance over a region 404 including the green and red regions as well as beyond the red region 404 is nearly 100%. The transmission curve 420 also includes a transition region or slope 406A or 406B may vary with a light incident angle. For example, slope 406A at 0 degree angle of incidence (AOI) is steeper than slope 406B at 45 degree AOI.

The transmittance blue region 402 has a reflection band bandwidth 408, which may vary with coating materials for layers 302 of a first refractive index and layers 304 of a second refractive index in the DCF 210. The reflection band width 408 often increases with the refractive index difference between the two coating materials having the first refractive index and the second refractive index.

The DCF 210 has a different function from the color filters 122 for the conventional LCD 100, because the conventional color filters 122 absorb a light in a color band while the DCF 210 reflects a light in the reflection band 408. Thus, the DCF 210 generates less heat than the color filters 122. The DCF 210 also has a longer life than the color filters 122.

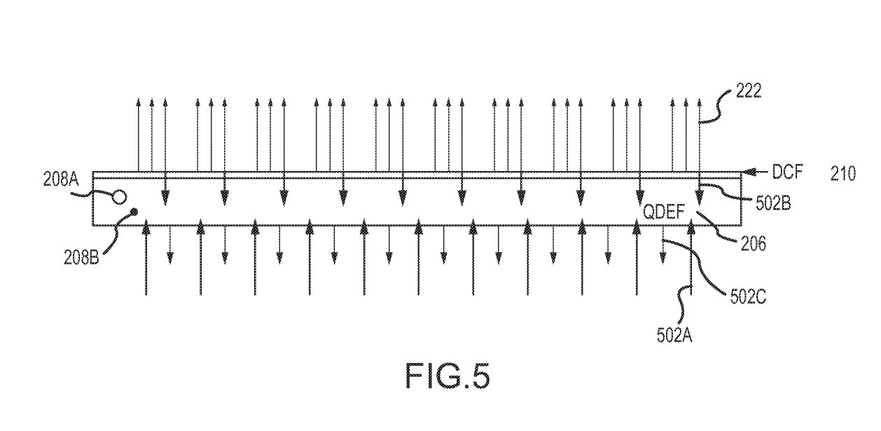

FIG. 5 illustrates recycling blue light in the QDEF in an embodiment. A larger portion 502B of the incoming blue light 502A is reflected by the DCF 210. A portion of this reflected blue light will excite the red QDs 208A and green QDs 208B in the QDEF 206 to increase the output of the red light and green light. This is a first order recycling. The red and green QDs 208A and 208B also diffuse the incoming blue light 502A more to help increase uniformity of a white light 222 through the DCF 210, which is one of the benefits of including the DCF in the QD enhanced display 200. A remaining portion 502C of the reflected blue light 502B will enter the light guide panel 112 (not shown) and reflected from the reflector 218 at the bottom of the LGP 204 and will re-enter the QDEF 206 again and excite more red and green QDs 208A and 208B. Again, a portion of the remaining portion 502C will be reflected again by the DCF 210, which is the second order recycling. This recycling will continue until no blue light will be reflected by the dichroic filter 210.

The dichroic filter 210 helps reduce the density of the red and green quantum dots 208A and 208B through recycling the blue light 502, which increases the emissions from each red QD 208A and green QD 208B. This reduction in QD density leads to less CdSe used in the quantum dot-enhanced liquid crystal display 200, which helps achieve a lower Cd content to meet the Cd free requirement of consumer goods.

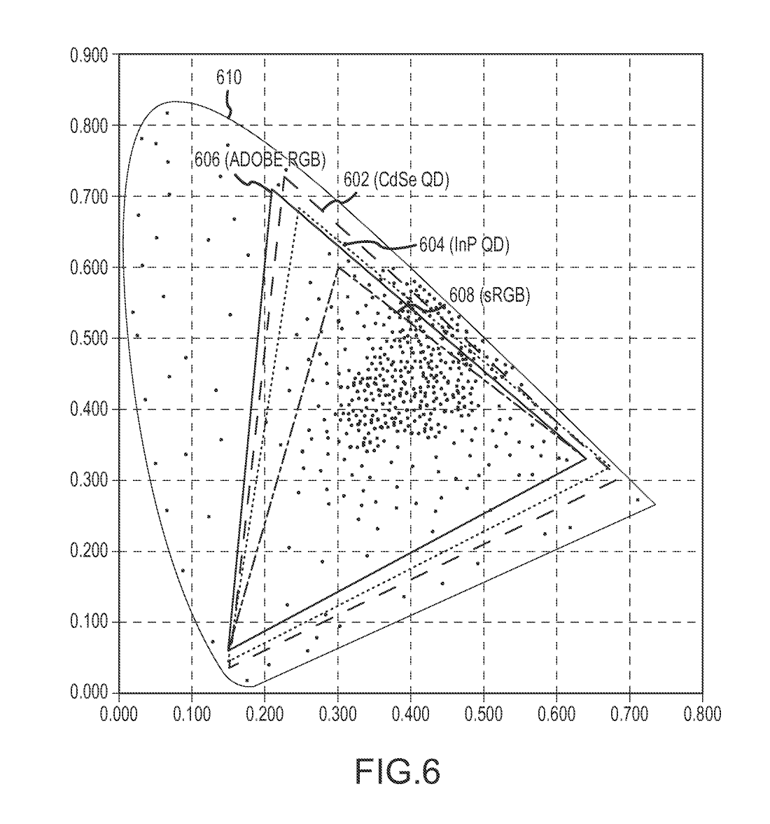

FIG. 6 illustrates color gamuts for the quantum dot-enhanced display and the LCD of FIG. 2. A color gamut is a portion of the color space that may be reproduced or represented. For example, color gamuts 602 (CdSe QD), 604 (InP QD), 606 (Adobe RGB) and 608 (standard RGB or sRGB) are a portion of real color space 610. Currently, conventional LCD 100 meets the standard color gamut 608, also labeled as “sRGB”. To provide a more full color than the conventional LCD 100, newer color gamut 606, also labeled as “Adobe RGB”, is desired, because newer color gamut 606 has a larger area than the standard color gamut 608 and is closer to real color space 610. As shown in FIG. 6, the QD enhanced LCD 200 is better than the conventional LCD (e.g. sRGB), because the CdSe QD color gamut 602 and InP QD color gamut 604 for the QD enhanced LCD 200 have larger triangle areas than the standard color gamut 608 of the conventional LCD 100.

Additionally, the color saturation of the CdSe QD enhanced display is more close to the desired Adobe RGB or better than the InP QD enhanced display. Although InP QD enhanced display 200 is a Cd free consumer product, its color gamut is not as good as the CdSe QD enhanced display. For the CdSe QD enhanced display with wider color gamut, the Cd content may be reduced below a threshold by including the DCF 210 to recycle blue light and thus reduce QD density, which is essentially considered Cd free, or comparable to the InP QD enhanced display.

The QD enhanced display 200 with the QDEF 206 and the DCF 210 is characterized by better color accuracy and narrow bandwidth as well as or wider color gamut than the conventional LCD 100. The conventional LCD can't produce pure red, green and blue for the display. Instead, the LCD needs to add a few other colors to the Red, Green and Blue colors.

The QD enhanced display 200 is generally much brighter than the conventional LCD display 100 as a result of its wider color gamut. The quantum dot-enhanced display 200 using a blue LED as a backlight, may have a power efficiency similar to conventional LCD 100 using a white LED backlight. However the QD-enhanced display 200 typically has a much wider color gamut than the conventional LCD backlit with a white LED. In other words, for conventional LCD 100 to achieve the same color gamut as the quantum dot-enhanced display 200, the power efficiency would be much lower than the quantum dot-enhanced display.

Furthermore, some light loss may occur during blue light recycling by the DCF 210. However, by using highly transmitted in some color regions such as red and green and highly reflected materials in other color region such as blue region for the DCF 210, the light loss may be reduced and/or minimized. In addition, the DCF may help reduce quenching and thus may increase the power efficiency. These two factors affect the power efficiency and may cancel each other when taken together in a system, such that about the same electrical power may be consumed by an LCD using the DCF 210 as without the DCF 210.

The quantum dot includes a material selected from the group consisting of a group II-VI compound, a group III-V compound, a group IV-VI compound, a group IV compound, and mixtures of these groups.

The group II-VI compound includes a material selected from the group consisting of CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe.

The group III-V compound includes a material selected from the group consisting of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb.

The group IV-VI compound comprises a material selected from the group consisting of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe.

The group IV compound comprises a material selected from the group consisting of Si, Ge, SiC, and SiGe.

Having described several embodiments, it will be recognized by those skilled in the art that various modifications, alternative constructions, and equivalents may be used without departing from the spirit of the invention. Additionally, a number of well-known processes and elements have not been described in order to avoid unnecessarily obscuring the present invention. Accordingly, the above description should not be taken as limiting the scope of the invention.

Those skilled in the art will appreciate that the presently disclosed embodiments teach by way of example and not by limitation. Therefore, the matter contained in the above description or shown in the accompanying drawings should be interpreted as illustrative and not in a limiting sense. The following claims are intended to cover all generic and specific features described herein, as well as all statements of the scope of the present method and system, which, as a matter of language, might be said to fall therebetween.

What is claimed is:

1. A display device, the device comprising:
a light source emitting a first light of a first color;
a light emitting layer comprising a first group of quantum dots and a second group of quantum dots, the light emitting layer configured to absorb a first portion of the first light from the light source to emit a second light of a second color and a third light of a third color and further configured to transmit a second portion of the first light; and
a dichroic filter layer configured to reflect a portion of the transmitted second portion of the first light such that the reflected portion of the first light is recycled in the light emitting layer, and further configured to transmit a remaining portion of the transmitted second portion of the first light, the second light, and the third light to output a white light.

2. The display device of claim 1, further comprising a light guide panel between the light source and the light emitting layer, the light guide panel configured to provide uniform incoming light to the light emitting layer.

3. The display device of claim 1, further comprising a liquid crystal display including a front polarizer, a rear polarizer, and a liquid crystal layer between the first polarizer and the second polarizer, a plurality of color filters between the front polarizer and the liquid crystal layer, the liquid crystal display configured to control pass of the white light from the dichroic filter through the color filters arranged in subpixels.

4. The display device of the claim 3, further comprising a brightness enhancement layer between the dichroic filter layer and the liquid crystal display configured to recycle the white light that does not pass through the rear polarizer to increase brightness.

5. The display device of claim 3, further comprising a prism between the dichroic filter and the liquid crystal display configured to reduce beam angle and to increase the intensity of the white light.

6. The display device of claim 1, wherein the quantum dots comprise a material selected from the groups consisting of a group II-VI compound, a group III-V compound, a group IV-VI compound, a group IV compound, and mixtures of these groups.

7. The display device of claim 6, wherein the group II-VI compound comprises a material selected from the groups consisting of CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe.

8. The display device of claim 6, wherein the group III-V compound comprises a material selected from the group consisting of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb.

9. The display device of claim 6, wherein the group IV-VI compound comprises a material selected from the group consisting of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe.

10. The display device of claim 6, wherein the group IV compound comprises a material selected from the group consisting of Si, Ge, SiC, and SiGe.

11. A display device, the device comprising:
a light source emitting a first light;
a light emitting layer comprising a first group of quantum dots and a second group of quantum dots, the light emitting layer configured to absorb a first portion of the first light from the light source to emit a second light of a second color and a third light of a third color and further configured to transmit a second portion of the first light;
a dichroic filter layer configured to reflect a portion of the transmitted second portion of the first light such that the reflected portion of the first light is recycled in the light emitting layer and to transmit a remaining portion of the transmitted second portion of the first light, the second light, and the third light to output a white light; and
a liquid crystal display including a front polarizer, a rear polarizer, and a liquid crystal layer between the first polarizer and the second polarizer, a plurality of color filters between the front polarizer and the liquid crystal layer, the liquid crystal display configured to control pass of the white light from the dichroic filter through the color filters arranged in subpixels.

12. The display device of claim 11, further comprising a light guide panel between the light source and the light emitting layer, the light guide panel configured to provide uniform incoming light to the light emitting layer.

13. The display device of the claim 11, further comprising a brightness enhancement layer between the dichroic filter layer and the liquid crystal display configured to recycle the white light that does not pass through the rear polarizer to increase brightness.

14. The display device of claim 11, further comprising a prism between the dichroic filter and the liquid crystal display configured to reduce beam angle and to increase the intensity of the white light.

15. The display device of claim 11, wherein the quantum dots comprise a material selected from the groups consisting of a group II-VI compound, a group III-V compound, a group IV-VI compound, a group IV compound, and mixtures of these groups.

16. The display device of claim 15, wherein the group II-VI compound comprises a material selected from the groups consisting of CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe.

17. The display device of claim 15, wherein the group III-V compound comprises a material selected from the group consisting of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb.

18. The display device of claim 15, wherein the group IV-VI compound comprises a material selected from the group consisting of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe.

19. The display device of claim 15, wherein the group IV compound comprises a material selected from the group consisting of Si, Ge, SiC, and SiGe.

20. A display device, the device comprising:
a light source emitting a blue light;
a light emitting layer comprising a first group of red quantum dots and a second group of green quantum dots, the light emitting layer configured to absorb a first portion of the blue light from the light source to emit red light and green light and further configured to transmit a second portion of the blue light; and
a dichroic filter layer configured to reflect a portion of the transmitted second portion of the blue light such that the reflected portion of the first blue is recycled in the light emitting layer and to transmit a remaining portion of the transmitted second portion of the blue light, the red light, and the green light to output a white light.
